(19) United States
(12) Patent Application Publication
(10) Pub. No.: US 2025/0351632 A1
(43) Pub. Date: Nov. 13, 2025

(54) METHOD FOR MANUFACTURING A PLURALITY OF SEMICONDUCTOR CHIPS AND SEMICONDUCTOR CHIP

(71) Applicant: ams-OSRAM International GmbH, Regensburg (DE)

(72) Inventor: Jens Müller, Regensburg (DE)

(21) Appl. No.: 18/861,117

(22) PCT Filed: Jan. 30, 2023
(86) PCT No.: PCT/EP2023/052135

§ 371 Date: Oct. 28, 2024

(30) Foreign Application Priority Data
May 3, 2022 (DE) 102022204348.0

(51) Int. Cl. H10H 20/857; H01L 25/16; H10H 20/01; H10H 20/85; H10H 20/854

(52) U.S. Cl. CPC H10H 20/857; H01L 25/167; H10H 20/0362; H10H 20/8506; H10H 20/854

(57) ABSTRACT

In an embodiment a method for manufacturing a plurality of semiconductor chips includes providing an epitaxial semiconductor layer sequence having a plurality of epitaxial semiconductor layer stacks, the epitaxial semiconductor layer stacks having active regions configured for generating electromagnetic radiation, applying a plurality of logical chips on or over the epitaxial semiconductor layer sequence, the logical chips including at least one integrated circuit configured for controlling the active regions, wherein the logical chips are at least partially provided separately from each other, and wherein the logical chips are CMOS chips, the CMOS chips including at least one p-channel MOSFET and at least one n-channel MOSFET being part of the at least one integrated circuit, and embedding the plurality of logical chips in a mold compound.

### CROSS-REFERENCE TO RELATED APPLICATIONS

This patent application is a national phase filing under section 371 of PCT/EP2023/052135, filed Jan. 30, 2023, which claims the priority of German patent application 10 2022 204 348.0, filed May 3, 2022, each of which is incorporated herein by reference in its entirety.

### TECHNICAL FIELD

A method for manufacturing a plurality of semiconductor chips and a semiconductor chip are provided.

### SUMMARY

Embodiments provide a method for manufacturing a semiconductor chip, particularly integrating a logical chip and a light-emitting epitaxial semiconductor layer stack. Further embodiments provide an improved semiconductor chip, particularly comprising a light-emitting epitaxial semiconductor layer stack and a logical chip.

According to an embodiment of the method for manufacturing a plurality of semiconductor chips, an epitaxial semiconductor layer sequence having a plurality of epitaxial semiconductor layer stacks is provided. The epitaxial semiconductor layer stacks are generated by singulation of the epitaxial semiconductor layer sequence in separated semiconductor chips. Therefore, features and embodiments disclosed in connection with the epitaxial semiconductor layer sequence are also disclosed for the epitaxial semiconductor layer stacks and vice versa.

The epitaxial semiconductor layer sequence has an active region configured for generating electromagnetic radiation, particularly visible light, during operation. After singulation each epitaxial semiconductor layer stacks comprises an active region configured for generating electromagnetic radiation, particularly visible light, during operation. Particularly, the epitaxial semiconductor layer stacks are configured to emit visible light during operation.

For example, the epitaxial semiconductor layer sequence is based on a III-V semiconductor compound material such as a nitride semiconductor compound material. In particular, an active region comprising or consisting of a nitride semiconductor compound material is configured to generate blue to ultraviolet light during operation. Nitride semiconductor compound materials are compound semiconductor materials containing nitrogen, such as the materials from the system InₓAl_{y}Ga_{1-x-y}N with 0≤x≤1, 0≤y≤1 and x+y≤1.

It is also possible that the epitaxial semiconductor layer sequence is based on or consists of a phosphide semiconductor compound material or an arsenide semiconductor compound material. Phosphide compound semiconductor materials are compound semiconductor materials containing phosphorus, such as the materials from the system InₓAl_{y}Ga_{1-x-y}P with 0≤x≤1, 0≤y≤1 and x+y≤1. Arsenide compound semiconductor materials are compound semiconductor materials containing arsenic, such as the materials from the system InₓAl_{y}Ga_{1-x-y}As with 0≤x≤1, 0≤y≤1 and x+y≤1.

A thickness of the epitaxial semiconductor layer sequence is, for example, between 1 micrometers and 10 micrometers, limits inclusive.

According to a further embodiment of the method, a plurality of logical chips is applied on or over the epitaxial semiconductor layer sequence. The logical chips comprise integrated circuits for controlling the active regions. In particular, one logical chip is applied on or over each epitaxial semiconductor layer stack. It is also possible, that more than one logical chip is applied on or over each epitaxial semiconductor layer stack. Further, one logical chip comprises at least one integrated circuit for controlling one active region, in particular. The logical chips of the plurality of logical chips may be embodied equal or different from each other at least partially. Further, features and embodiments disclosed in connection with one logical chip are also disclosed for some or all logical chips and vice versa. The logical chips can be thinned before or after being applied on or over the epitaxial semiconductor layer sequence.

The term “on or over” particularly indicates that the two elements thus related to each other do not necessarily have to be in direct physical contact with each other. Rather, further elements may be arranged between them.

For example, the logical chip has a thickness between 20 micrometer and 1000 micrometer, limits inclusive. It is also possible that the logical chip has a thickness between 50 micrometer and 200 micrometer, limits inclusive. For example, the logical chip has a thickness of about 120 micrometer.

For example, the logical chip has a width larger than the width of the epitaxial semiconductor layer stack or vice versa. Further, it is possible that the logical chip is arranged offset to the epitaxial semiconductor layer stack.

According to a further embodiment of the method, the plurality of logical chips is embedded in a mold compound. In particular, the embedding takes place such that the logical chips form an artificial wafer together with the mold compound. Preferably, the mold compound embeds at least the logical chips and forms a continuous plane surface over the logical chips. In particular, after embedding the plurality of logical chips in the mold compound, the logical chips are not freely accessible anymore without a further process step such as grinding or polishing. The mold compound mechanically stabilizes the logical chips and the whole compound formed together with the epitaxial semiconductor layer sequence.

For example, the mold compound is an epoxy resin or a spin-on glass or comprises such a material. The thickness of the compound comprising the epitaxial semiconductor layer sequence, the logical chips and the mold compound is, for example, between 500 micrometer and 1 millimeter, limits inclusive. It is also possible that the thickness of the compound comprising the epitaxial semiconductor layer sequence, the logical chips and the mold compound is between 300 micrometer and 1000 micrometer, limits inclusive. Particularly, steps in the compound comprising the epitaxial semiconductor layer sequence and the logical chips are overmolded by the mold compound in order to create a planar outer surface of the mold compound. For example, the embedding takes place by casting, transfer molding or foil-assisted molding.

According to an embodiment, the method comprises the following steps:
providing an epitaxial semiconductor layer sequence having a plurality of epitaxial semiconductor layer stacks, said epitaxial semiconductor layer stacks having active regions configured for generating electromagnetic radiation during operation,
applying a plurality of logical chips on or over the epitaxial semiconductor layer sequence, said logical chips comprising integrated circuits for controlling the active regions, and
embedding the plurality of logical chips in a mold compound.

Particularly, the method steps mentioned above are carried out in the given order.

It is an idea of the present application to provide the light-emitting epitaxial semiconductor layer stacks as a wafer and to apply the logical chips to the wafer. In particular, the epitaxial semiconductor layer sequence is provided as a wafer comprising all of the non-separated epitaxial semiconductor layer stacks. Such a method for manufacturing a plurality of semiconductor chips on wafer level is simplified. In particular, the logical chips have usually a smaller bow than the epitaxial semiconductor layer stacks. Manufacturing is simplified, when providing the epitaxial semiconductor layer stacks as part of an epitaxial semiconductor layer sequence. Mechanical stability of the whole compound comprising the light-emitting epitaxial semiconductor layer sequence and the logical chips during manufacturing is particularly achieved with the help of the mold compound.

According to a further embodiment of the method, the epitaxial semiconductor layer sequence is provided arranged on a carrier. For example, the carrier is a growth substrate for the epitaxial semiconductor layer sequence. If an epitaxial semiconductor layer sequence is provided, which is based on a nitride semiconductor compound material or consists of a nitride semiconductor compound material, the growth substrate is, for example, sapphire, silicon carbide or gallium nitride. A growth substrate comprising or consisting of sapphire or silicon carbide is, for example, removed from the epitaxial semiconductor layer sequence based on a nitride compound semiconductor material by a laser lift-off method. In particular, the carrier stabilizes the compound comprising the epitaxial semiconductor layer sequence and the logical chips mechanically before the mold compound is applied. Between the epitaxial semiconductor layer sequence and the carrier one or more mirror layers can be arranged.

According to a further embodiment of the method the epitaxial semiconductor layer sequence comprises an n-doped semiconductor layer and a p-doped semiconductor layer, wherein the active regions are arranged between the n-doped semiconductor layer and the p-doped semiconductor layer. In particular, the n-doped semiconductor layer is exposed when the carrier is removed. Therefore, it is possible to further process the n-doped semiconductor layer after removing the carrier. For example, the n-doped semiconductor layer is roughened in order to enhance light output from the roughened surface. Further, protection structures and/or contrast enhancement structures can be processed as described later. If the epitaxial semiconductor layer sequence is separated in epitaxial semiconductor layer stacks, the epitaxial layer stacks each comprises an n-doped semiconductor layer and an p-doped semiconductor layer, wherein the active regions are arranged between the n-doped semiconductor layer and the p-doped semiconductor layer.

According to a further embodiment of the method, the mold compound is removed against a vertical direction such that backside surfaces of the logical chips are exposed. The vertical direction corresponds to a stacking direction of the epitaxial semiconductor layer sequence, which corresponds also to the growth direction of the epitaxial semiconductor layer sequence. For example, the mold compound is removed against the vertical direction by grinding or polishing.

After removing the mold compound against the vertical direction, a metal layer is applied on the exposed backside surface of the logical chips. For example, the metal layer comprises gold or a gold tin alloy or consists of one of these materials. In particular, the gold tin alloy is solderable for electrically conductively connecting the logical chip to a further element, such as a communication chip. The thickness of the metal layer is between 100 nanometer and 500 nanometer, limits inclusive or between 100 nanometer and 5 micrometer, limits inclusive. Instead or additionally to the metal layer, an adhesive layer can be applied. In particular, the mold compound is removed and the metal layer and/or the adhesive layer is applied on the backside surface of the logical chips before singulation of the whole compound into single semiconductor chips is carried out.

According to a further embodiment of the method, electrical contact pads of the logical chips are exposed, in particular after removing the carrier. For exposing the electrical contact pads of the logical chips, particularly material of the epitaxial semiconductor layer sequence is removed above the electrical contact pads in the vertical direction, for example by plasma etching based on chlorine. Further, it is possible to use wet chemical etching for removing the material of the epitaxial semiconductor layer sequence above the electrical contact pads of the logical chips. During etching, a mask can cover the epitaxial semiconductor layer stacks of the epitaxial semiconductor layer sequence for protection against the etching process.

According to a further embodiment of the method, the mold compound on or over the electrical contact pads of the logical chips is also removed in the vertical direction, for example by incineration. Preferably, the mold compound is removed together or after the semiconductor material of the epitaxial semiconductor layer sequence on or over the electrical contact pads of the logical chips is removed.

According to a further embodiment of the method, the plurality of semiconductor chips is singulated into single semiconductor chips being separated from each other along separation lines running through the mold compound between the logical chips. In particular, by singulating the plurality of semiconductor chips, the epitaxial semiconductor layer sequence is divided into a plurality of epitaxial semiconductor layer stacks. Particularly, each singulated semiconductor chip comprises one epitaxial semiconductor layer stack having a n-doped semiconductor layer, a p-doped semiconductor layer and an active region arranged between. Singulation of the plurality of the semiconductor chips can take place by sawing or by laser cutting.

According to a further embodiment of the method, the logical chips are at least partially provided separately from each other before applying on or over the epitaxial semiconductor layer sequence. For example, the logical chips are separate from each other and serially applied on or over the epitaxial semiconductor layer sequence. It is also possible that some of the logical chips are at least partially transferred to the epitaxial semiconductor layer sequence in a parallel manner. For example, several logical chips can be applied in a parallel manner with the help of a stamp mechanically connecting the logical chips to each other.

Further, it is possible that the logical chips are provided continuously connected to each other in a wafer compound. In particular, the logical chips can be applied to the epitaxial semiconductor layer sequence on wafer level.

According to a further embodiment of the method, the logical chips are CMOS chips (“CMOS” short for “Complementary Metal Oxide Semiconductor”). The CMOS chips comprise at least one p-channel MOSFET (“MOSFET” short for “Metal Oxide Semiconductor Field-Effect Transistor”) and at least one n-channel MOSFET being part of the at least one integrated circuit. A predetermined logic operation of the CMOS chip is for example developed as one or more p-channel MOSFETs and as one or more n-channel MOSFETs and combined in one or more integrated circuits. If one p-channel MOSFET of the p-channel and one n-channel MOSFET of the n-channel have the same control voltage, always exactly one MOSFET blocks, while the other MOSFET is conductive.

According to a further embodiment of the method, protection structures are applied to the epitaxial semiconductor layer sequence before the mold compound is applied. It is possible that the protection structures are applied before or after the logical chips are applied. Particularly, the protection structures are applied on or over the epitaxial semiconductor layer sequence in regions not intended to be applied with logical chips or between the logical chips. For example, the protection structures are walls applied by plating on or over the epitaxial semiconductor layer sequence. For example, the protection structures comprise one of the following materials or consist of one of the following materials: copper, nickel, gold, aluminum. For example, the protection structures have a height of at least 20 micrometer or of at least 100 micrometer and a width between 10 micrometer and 50 micrometer, limits inclusive.

According to a further embodiment of the method, the protection structures exceed the logical chips in the vertical direction. The protection structures are intended to protect the logical chips as well as the epitaxial semiconductor layer stack in the finished semiconductor chip by mechanical support in combination with the mold compound. Protection is enhanced with advantageous, if the protection structures exceed the sensitive parts of finished semiconductor chips such as the logical chip.

According to a further embodiment of the method, contrast enhancement structures are formed within the epitaxial semiconductor layer sequence separating the epitaxial semiconductor layer stacks in at least two pixel regions. For example, the contrast enhancement structures are embodied as a metal grid that can be grown or deposited in combination with dielectric layers for passivation and reflectivity. For example, the contrast enhancement structures can comprise silver, aluminum or gold as metal or consists of at least one of these materials. In particular, the contrast enhancement structures form a grid in plan view on the epitaxial semiconductor layer sequence. In particular, the contrast enhancement structures have enhanced specular reflectivity for electromagnetic radiation generated within the active region of the epitaxial semiconductor layer stacks. Thus the contrast enhancement structures separate the light generated in the active regions of adjacent pixel regions.

According to a further embodiment of the method, a plurality of communication chips is applied on or over the logical chips. In particular, the number of communication chips and the number of logical chips is equal such that each finished semiconductor chip comprises one logical chip and one communication chip.

Particularly, the communication chip communicates with the outer world by exchanging and processing signals, in particular electronic signals. The communication chip receives external signals, in particular external electronic signals, sent from an external device and processes the external signals such that an internal signal, in particular an internal electronic signal, is generated. Then, the communication chip sends the internal signal to the logical chip controlling the active region. For example, the communication chip is an I/O-chip. For example, the external electronic signal is a HDMI signal. For example, the plurality of communication chips is applied on or over the logical chips before singulation of the plurality of semiconductor chips. In other words, the plurality of communication chips is preferably applied on or over the logical chips on wafer level.

For example, the plurality of communication chips is applied on or over the logical chip at least partially separated from each other. The plurality of communication chips can be applied serially one after the other or at least partially in a parallel manner, for example by the help of a stamp. Further, it is possible that the communication chips are provided continuously connected to each other in a wafer compound when applied to the logical chips.

According to a further embodiment of the method, a wavelength converter is applied on or over a main surface of the epitaxial semiconductor layer sequence. For example, the wavelength converter comprises a resin such as a silicone with phosphor particles. The phosphor particles, for example, partially converting blue light generated by the active region into green to yellow light. In such a way the wavelength converter can produce white light together with the active region. For example, the phosphor particles generating green to yellow light comprise or consist a doped garnet with the stoichiometric formula (Lu,Y)3(Al,Ga)5O12:Ce3+, such as a LuAG with the stoichiometric formula Lu3Al5O12:Ce3+, a LuAGaG with the stoichiometric formula Lu3(Al,Ga)5O12:Ce3+ or a YAG with the stoichiometric formula Y3(Al,Ga)5O12:Ce3+.

If the epitaxial semiconductor layer stack of the epitaxial semiconductor layer sequence comprises at least two pixel regions, it is also possible that different wavelength converters are applied on or over different pixel regions. For example, one pixel region is covered with a wavelength converter converting electromagnetic radiation of the active region into red light, preferably completely, and another pixel region is covered with a wavelength converter converting electromagnetic radiation of the active region into green light, preferably completely. In such a way, pixels can be generated emitting light of different colors.

Phosphor particles converting blue light in red light can comprise or consist of a nitride material such as an alkaline earth silicon nitride, an oxynitride, an aluminum oxynitride, a silicon nitride or a sialon. For example, the nitride phosphor has one of the following stoichiometric formulas: (Ca,Sr,Ba)AlSiN3:Eu2+, (Ca,Sr)AlSiN3:Eu2+, Sr(Ca,Sr)Al2Si2N6:Eu2+, M2Si5N8:Eu2+ with M=Ca, Ba or Sr alone or in combination.

For example, the wavelength converter is applied by spray coating, spin coating, doctor blading, printing such as screen printing, or jetting.

The method described can be used to produce a plurality of semiconductor chips as described in the following. All features and embodiments disclosed in connection with the method can therefore also be embodied with the semiconductor chip and vice versa.

According to an embodiment, the semiconductor chip comprises an epitaxial semiconductor layer stack having an active region configured for generating electromagnetic radiation during operation.

According to a further embodiment, the semiconductor chip comprises a logical chip with at least one integrated circuit configured to control the active region. For example, the semiconductor chip comprises at least one logical chip. In particular, if the logical chip is a CMOS chip optimal nodes of CMOS technologies can be mixed for optimization.

According to a further embodiment of the semiconductor chip, the logical chip is laterally at least partially embedded in a mold compound. In particular, a side surface of the logical chip is at least partially in direct contact with the mold compound.

According to an embodiment, the semiconductor chip comprises an epitaxial semiconductor layer stack having an active region configured for generating electromagnetic radiation during operation and a logical chip comprising at least one integrated circuit configured to control the active region, wherein the logical chip is laterally at least partially embedded in a mold compound.

According to a further embodiment of the semiconductor chip, the epitaxial semiconductor layer stack has at least two pixel regions comprising parts of the active region. In other words, each pixel region comprises a part of the active region. Further, the semiconductor chip comprises bumps electrically conductively connecting the pixel regions with the logical chip. Further, the logical chip controls the parts of the active region of the pixel regions independently from each other. In particular, the semiconductor chip comprises at least two bumps, each bump electrically conductively connecting one pixel region with the logical chip.

Usually, the epitaxial semiconductor layer stack has a number of pixel regions and the equal number of bumps electrically conductively connecting the pixel regions with the logical chip. Each bump allows controlling the conductively connected pixel region independently from the other pixel regions. For example, the semiconductor chip has about 25.000 pixel regions and the equal number of bumps.

For example, a width of the pixel region is about 40 micrometer. The thickness of the bumps is, for example, 1 micrometer to 10 micrometer, limits inclusive.

According to a further embodiment of the semiconductor chip, at least outer bumps adjacent to side faces of the semiconductor chip are covered with a mold compound. Further, it is possible that the mold compound also fills cavities between inner bumps, preferably completely.

Instead of bumps, also plugs embedded into a passivation layer (e.g. Cu plugs in SiO) can be used as connecting the pixel regions with the logical chip.

According to a further embodiment of the semiconductor chip, the epitaxial semiconductor layer stack and the logical chip are arranged offset to each such that an electrical contact pad of the logical chip is freely accessible. For example, the electrical contact pad can be externally electrically conductively connected via a bond wire.

According to a further embodiment, the semiconductor chip comprises a communication chip. Preferably, the communication chip is applied on or over a backside surface of the logical chip. For example, the communication chip is connected to the backside surface of the logical chip by a bond layer.

The semiconductor chip can, for example, find application in an automotive lamp, in a projector or in a display.

### BRIEF DESCRIPTION OF THE DRAWINGS

Further advantageous embodiments and developments of the semiconductor chip and the method for manufacturing a plurality of semiconductor chips result from the exemplary embodiments described below in connection with the Figures.

FIGS. 1 to 7 show schematically sectional views of different stages of a method for manufacturing a plurality of semiconductor chips according to an exemplary embodiment;

FIG. 8 shows schematically a sectional view of a semiconductor chip according to an exemplary embodiment;

FIGS. 9 to 10 show schematically sectional views of different stages of a method for manufacturing a plurality of semiconductor chips according to a further exemplary embodiment;

FIGS. 11 to 12 show schematically sectional views of different stages of a method for manufacturing a plurality of semiconductor chips according to a further exemplary embodiment;

FIGS. 13 to 15 show schematically sectional views of different stages of a method for manufacturing a plurality of semiconductor chips according to a further exemplary embodiment;

FIG. 16 shows schematically a sectional view of a semiconductor chip according to an exemplary embodiment;

FIGS. 17 to 18 show schematically sectional views of different stages of a method for manufacturing a plurality of semiconductor chips according to a further exemplary embodiment;

FIG. 19 shows schematically a sectional view of a semiconductor chip according to a further exemplary embodiment;

FIG. 20 shows schematically a sectional view of a stage of a method for manufacturing a plurality of semiconductor chips according to a further exemplary embodiment; and

FIG. 21 shows schematically a sectional view of a semiconductor chip according to a further exemplary embodiment.

Equal or similar elements as well as elements of equal function are designated with the same reference signs in the Figures. The Figures and the proportions of the elements shown in the Figures are not regarded as being shown to scale. Rather, single elements, in particular layers, can be shown exaggerated in magnitude for the sake of better presentation and/or better understanding.

### DETAILED DESCRIPTION OF ILLUSTRATIVE EMBODIMENTS

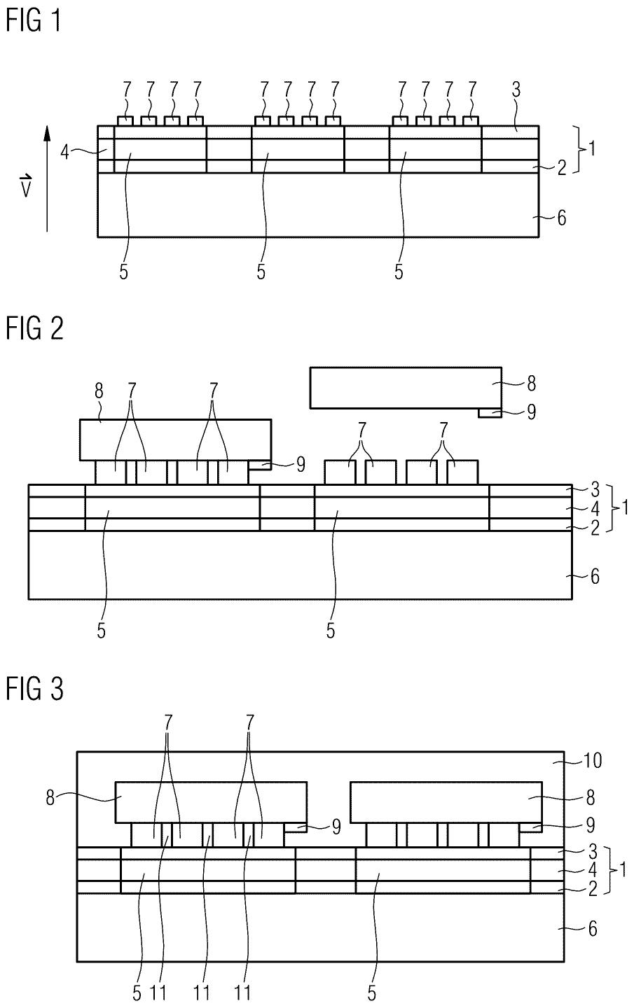

According to the method of the exemplary embodiment of FIGS. 1 to 7, an epitaxial semiconductor layer sequence is provided. The epitaxial semiconductor layer sequence 1 comprises a n-doped semiconductor layer 2, a p-doped semiconductor layer 3 and an active region 4 arranged between the n-doped semiconductor layer 2 and the p-doped semiconductor layer 3. Further, the epitaxial semiconductor layer sequence 1 comprises a plurality of epitaxial semiconductor layer stacks 5.

The epitaxial semiconductor layer sequence 1, with the epitaxial semiconductor layer stacks 5, is provided on a carrier 6, which is at present a growth substrate of the epitaxial semiconductor layer sequence 1. For example, the epitaxial semiconductor layer sequence 1, as well as the epitaxial semiconductor semiconductor layer stacks 5 being part of the epitaxial semiconductor layer sequence 1, is based on a nitride compound semiconductor material. For example, the growth substrate is sapphire or silicon carbide.

A vertical direction [symbol] is a stacking direction of the epitaxial semiconductor layer stacks 5 as well as a growth direction of the epitaxial semiconductor layers of the epitaxial semiconductor layer sequence 1. The epitaxial semiconductor layer stacks 5 have bumps 7 on a main surface for electrically conductive connection with a further element (FIG. 1).

In a further step, a plurality of logical chips 8 is arranged on the bumps 7 (FIG. 2). The logical chips 8 are at present CMOS chips comprising at least one integrated circuit with at least one n-channel MOSFET and one p-channel MOSFET. The integrated circuit of the CMOS chip is configured for controlling the active region 4 of the epitaxial layer semiconductor stack 5 to which the logical chip 8 is connected. For example, the CMOS chips are electrically conductively connected to the bumps 7 with the help of a solder or a conductive adhesive. Further the logical chips 8 comprise an electrical contact pad 9 for external electrical connection with a bond wire.

In a further step, the plurality of logical chips 8 is embedded in a mold compound 10 (FIG. 3). The mold compound 10 is, for example, an epoxy resin and embeds the logical chips 8 completely. In other words, the mold compound 8 fills all cavities 11 and gaps between the logical chips 8 as well as between the bumps 7. The logical chips 8 are completely embedded within the mold compound such that they are not freely accessible anymore after molding with the mold compound 10. Embedding, for example, takes place by transfer molding, foil-assisted molding or casting.

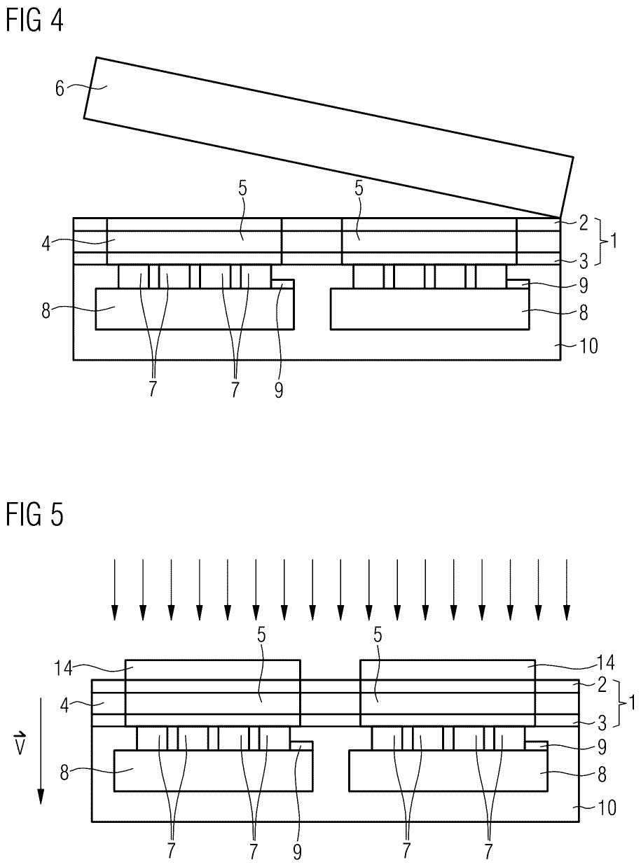

The carrier being a growth substrate of the epitaxial semiconductor layer sequence 1 is removed from the epitaxial semiconductor layer sequence 1, for example, by a laser lift-off method (FIG. 4).

After removal of the growth substrate, the n-doped semiconductor layer 2 of the epitaxial semiconductor layer sequence 1 is freely accessible from the outside and can be processed further, for example by roughening, providing with contrast enhancement structures 12 and/or providing with protection structures 13 as described later in further detail.

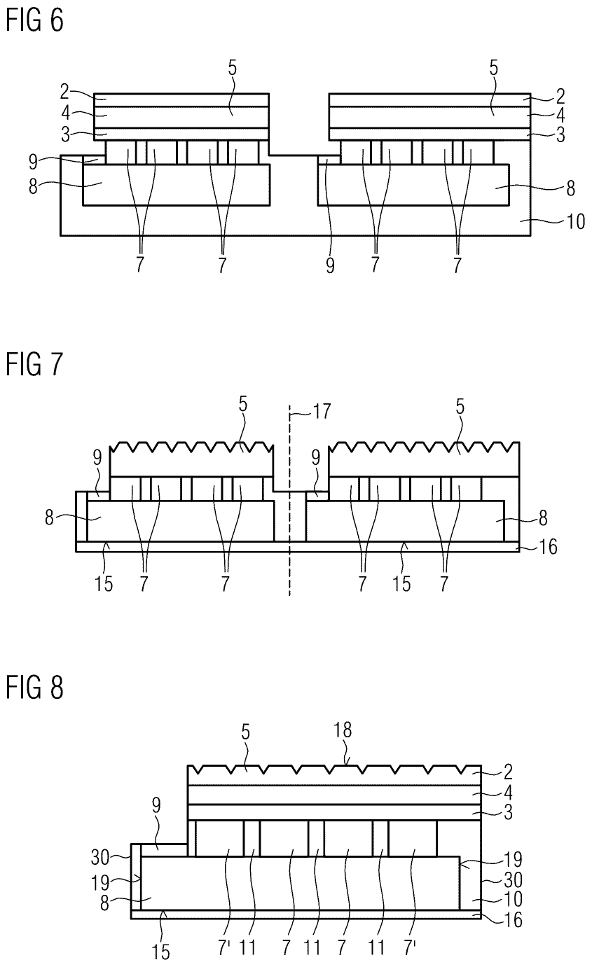

In a next step, material of the epitaxial semiconductor layer sequence 1 between the epitaxial semiconductor layer stacks 5 as well as material of the mold compound 10 is removed in the vertical direction [symbol] in order to expose the electrical contact pads 9 of the logical chips 8 (FIG. 5). For example, a mask 14 covers the epitaxial semiconductor layer stacks 5 during the removal in order to protect them during exposure of the electrical contact pads 9 of the logical chips 8. The material of the epitaxial semiconductor layer sequence 1 as well as of the mold compound 10 are, for example, removed by an etching process such as a wet chemical or dry chemical etching. For example, the material of the epitaxial semiconductor layer sequence 1 as well as of the mold compound 10 is removed by plasma etching based on chlorine. The mask 14 is removed after the etching (FIG. 6).

In a next step, a main surface of the epitaxial semiconductor layer sequence 1 is roughened in order to enhance light outcoupling from this surface of the finished semiconductor chip.

In a next step, the mold compound 10 is removed against the vertical direction [symbol] such that backside surfaces 15 of the logical chips 8 are freely accessible. In other words, the mold compound 10 is removed in a direction running opposite to the vertical direction [symbol] . If the mold compound 10 is removed such that the backside surfaces 15 of the logical chips 8 are freely accessible, a metal layer 16 is applied on the backside surface 15 of the logical chips 8, for example in direct contact.

Then, the semiconductor chips are singulated along separation lines 17, for example by sawing (FIG. 7).

The semiconductor chip of the exemplary embodiment of FIG. 8 can be manufactured with the method according to the exemplary embodiment of FIGS. 1 to 7.

The semiconductor chip according to the exemplary embodiment of FIG. 8 comprises an epitaxial semiconductor layer stack 5 having an n-doped semiconductor layer 2, a p-doped semiconductor layer 3 and an active region 4 arranged between the n-doped semiconductor layer 2 and the p-doped semiconductor layer 3. A main surface 18 of the epitaxial semiconductor layer stack 5 being intended for light outcoupling is roughened in order to enhance the light outcoupling from the semiconductor chip.

Further, the semiconductor chip of FIG. 8 comprises a logical chip 8 conductively connected to bumps 7 of the epitaxial semiconductor layer stack 5. The logical chip 8 comprises an integrated circuit configured to control the active region 4 of the epitaxial semiconductor layer stack 5. Furthermore, the logical chip 8 comprises an electrical contact pad 9 being freely accessible. The epitaxial semiconductor layer stack 5 is arranged offset to the logical chip 8. Therefore, the electrical contact pad 9 of the logical chip 8 is freely accessible. The electrical contact pad 9 can, for example, be electrically conductively connected externally by a bond wire. The logical chip 8 supplies the active region 4 of the epitaxial semiconductor layer stack 5 with power via the bumps 7 during operation.

Further, the semiconductor chip of the exemplary embodiment of FIG. 8 comprises a mold compound 10 laterally embedding the logical chip 8 and the bumps 7. In particular, side faces 19 of the logical chip 8 are covered with the mold compound. Also, cavities 11 between the bumps 7 are completely filled with the mold compound 10. Additionally, side faces of the outer bumps 7′ are covered with the mold compound. The outer bumps 7′ are adjacent to a side face 30 of the semiconductor chip.

A backside surface 15 of the logical chip 8 is covered with a metal layer 16. For example, the metal layer 16 comprises a solderable material such as a gold tin alloy. Beside the backside surface 15 of the logical chip 8 the metal layer 16 also covers the mold compound 10 laterally.

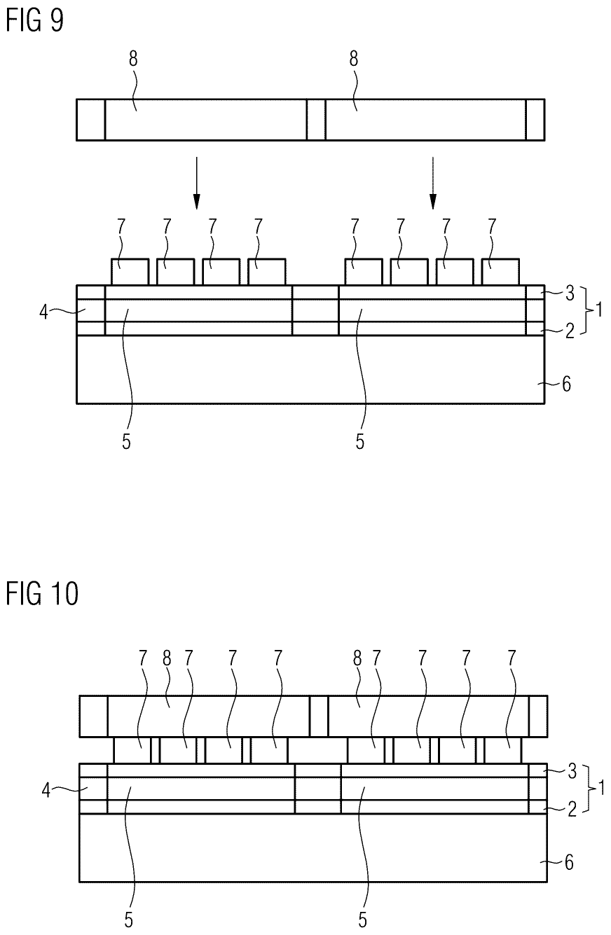

During the method according to the exemplary embodiment of FIGS. 9 to 10 an epitaxial semiconductor layer sequence 1 is provided, as already described in connection with FIG. 1. Then, a plurality of logical chips 8 is provided continuously connected to each other in a wafer compound (FIG. 9). The wafer compound with the logical chips 8 is applied to bumps 7 of the epitaxial semiconductor layer stacks 5 of the epitaxial semiconductor layer sequence 1 (FIG. 10).

Then, the method steps as already described in connection with FIGS. 3 to 7 can be carried out.

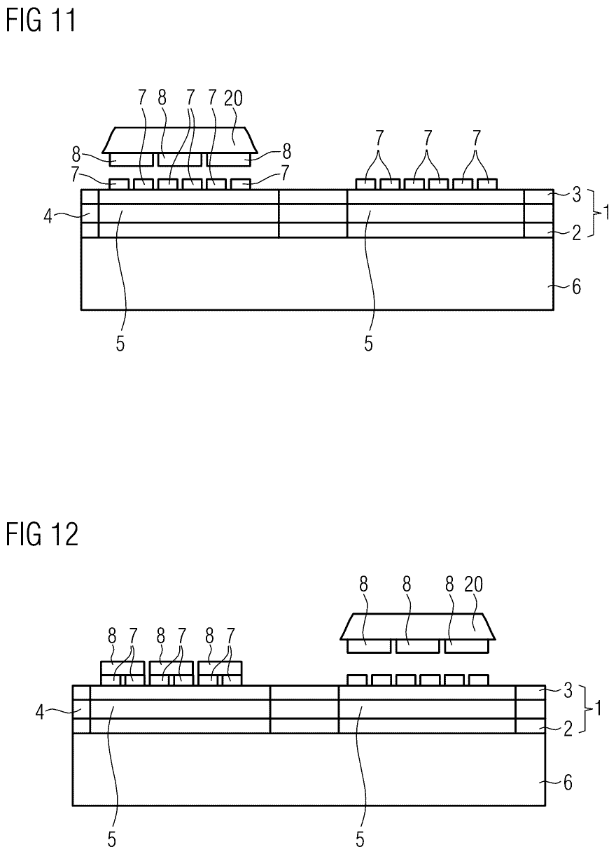

During the method according to the exemplary embodiment of FIGS. 11 and 12, an epitaxial semiconductor layer sequence 1 as already described in connection with FIG. 1 is provided. Then, logical chips 8 are connected by a stamp 20 and, in parallel, applied to the bumps 7 of epitaxial semiconductor layer stacks 5 of the epitaxial semiconductor layer sequence 1 (FIG. 12).

Again, the method steps as already described in connection with FIGS. 3 to 7 can be carried out.

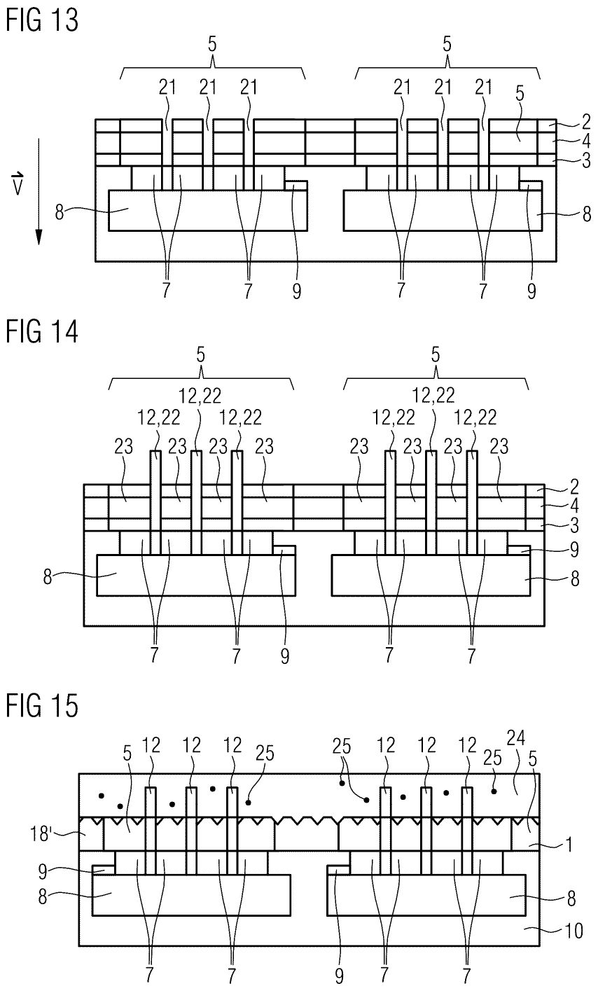

During the method according to the exemplary embodiment of FIGS. 13 to 15 the method steps as described in connection with FIGS. 1 to 4 are carried out at first. Then, contrast enhancement structures are generated within the epitaxial semiconductor layer stacks 5.

Then, slits 21 are etched into the epitaxial semiconductor layer stacks 5 in a vertical direction [symbol] . The slits 21 are arranged above cavities 11 between the bumps 7 being filled with a mold compound 10. In other words, the slits 21 are arranged within the epitaxial semiconductor layer stacks 5 such that the bumps 7 are still completely covered with the epitaxial semiconductor layer material (see FIG. 13).

In a further step, the slits 21 are filled with a specular reflective material 22 being specularly reflective in particular for the electromagnetic radiation generated within the active region 4 of the epitaxial semiconductor layer stacks 5 (FIG. 14). For example, the specular reflective material 22 is a metal or a layer sequence comprising a metal and dielectric materials. The specular reflective material 22 forms contrast enhancement structures 12 exceeding the epitaxial semiconductor layer stacks 5 at present. The contrast enhancement structures 12 separate the epitaxial semiconductor layer stack in pixel regions 23. The contrast enhancement structures 12 are arranged between pixel regions 23 of an epitaxial semiconductor layer stack 5.

In a further step, a wavelength converter 24 is applied on a main surface 18′ of the epitaxial semiconductor layer sequence 1, for example by spin coating (FIG. 15). The wavelength converter 24 embeds the part of the contrast enhancement structures 12 projecting from the epitaxial semiconductor layer stacks 5.

For example, the wavelength converter 24 comprises a resin with introduced phosphor particles 25, the phosphor particles 25 converting electromagnetic radiation of the active region 4 in electromagnetic radiation of a different wavelength range. For example, the phosphor particles 25 convert blue light generated in the active region 4 into yellow light.

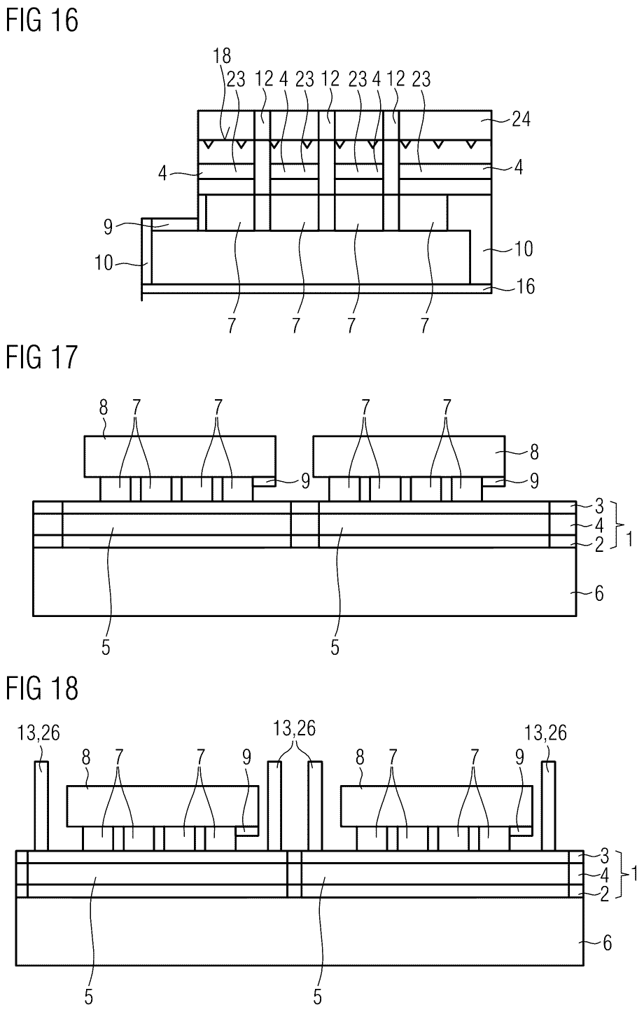

FIG. 16 shows an exemplary embodiment of a semiconductor chip, which can be produced with the method according to the exemplary embodiment of FIGS. 13 to 15.

In contrast to the semiconductor chip according to the exemplary embodiment of FIG. 8, the semiconductor chip according to the exemplary embodiment of FIG. 16 comprises pixel regions 23, each pixel region 23 being connected to the logical chip 8 by a bump 7. Contrast enhancement structures 12 are arranged between the pixel regions 23, formed for example of a metal or a combination of metal layers and dielectric layers.

A wavelength converter 24 is arranged on a main surface 18 of the epitaxial semiconductor layer stack 5. The wavelength converter 24 converts light generated in the active region 4 during operation, such as blue light, partially into yellow light. The semiconductor chip emits white light of unconverted blue light and converted yellow light during operation.

It is also possible that on the pixel regions 23 of the epitaxial semiconductor layer stack 5 different wavelength converter 23 are arranged producing light of different colors (not shown).

Preferably, the contrast enhancement structures 12 projects partially or completely through the wavelength converter 24 in order to separate the light generated within the active regions 4 of different pixel regions 23 during operation.

During the method of the exemplary embodiment of FIGS. 17 and 18 an epitaxial semiconductor layer sequence 1 comprising a plurality of epitaxial semiconductor layer stacks 5 arranged on a carrier 6 such as a growth substrate for the epitaxial semiconductor layer sequence 1 is provided. The epitaxial semiconductor layer stacks 5 comprise bumps 7 to which logical chips 8 are applied (FIG. 17).

In a further step, walls 26 are arranged as protection structures 13 surrounding the logical chips 8 completely (FIG. 18). Each logical chip 8 is surrounded by a wall 26 forming a protection structure 13. The protection structures 13 give mechanical support during the manufacturing method and also to the final semiconductor chip. Also, a bond wire connecting an electrical contact pad 9 of the logical chip 8 to an external device might be protected within the finished semiconductor chip by the protection structure 13.

The protection structure 13 preferably encapsulate the bumps 7 and the logical chip 8 from outside to enhance stability. For example, the protection structures 13 are plated before or after the logical chips 8 are applied to the epitaxial semiconductor layer sequence 1.

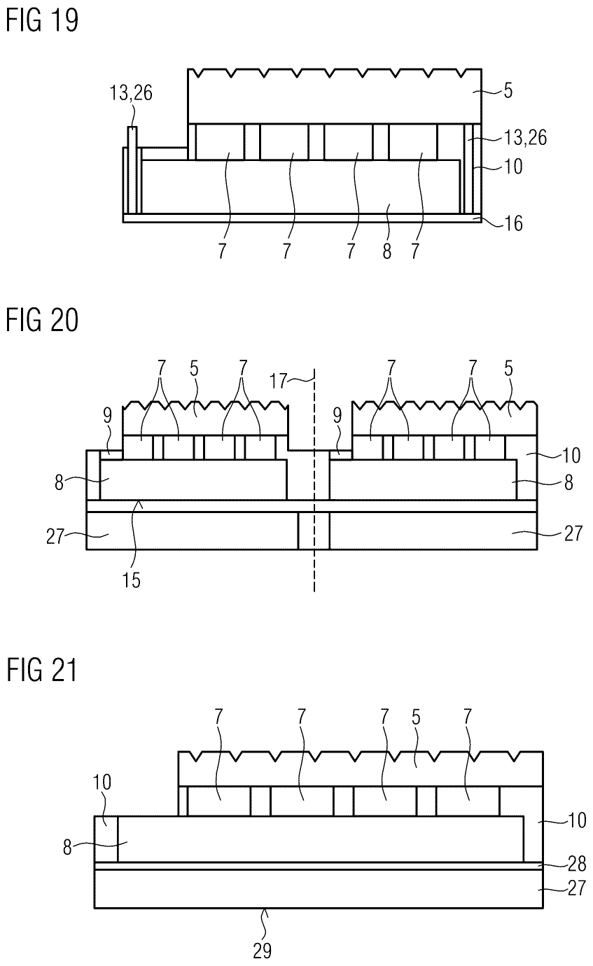

FIG. 19 shows an exemplary embodiment of a semiconductor chip which could be manufactured with the method according to FIGS. 17 to 18.

In contrast to the semiconductor chip of the exemplary embodiment of FIG. 8, the semiconductor chip according to the exemplary embodiment of FIG. 18 comprises a protection structure 13 embodied as a wall 26 completely surrounding the logical chip 8 laterally. The protection structure 13 is partially embedded in the mold compound 10. In particular, the protection structure 13 exceeds an electrical contact pad 9 of the logical chip 8 for protection.

During the method according to the exemplary embodiment of FIG. 20, the process steps as already described in connection with FIGS. 1 to 7 are carried out. Then, a plurality of communication chips 27 are continuously connected to each other in a wafer compound applied to a backside surface 15 of the logical chips 8 by a bond layer 28. Then, the generated wafer compound is separated into single semiconductor chips along separation lines 17 (FIG. 20).

FIG. 21 shows an exemplary embodiment of a semiconductor chip which could be manufactured with the method according to FIG. 20.

In contrast to the semiconductor chip according to the exemplary embodiment of FIG. 8, the semiconductor chip according to the exemplary embodiment of FIG. 21 comprises a communication chip 27 being applied to a backside surface 15 of the logical chip 8 by a bond layer 28.

Further, the semiconductor chip according to the exemplary embodiment of FIG. 21 does not comprise an electrical contact pad 9 being part of the logical chip 8. Instead electrical connection of the semiconductor chip takes place via a backside surface 29 of the communication chip 27. In particular, the bond layer 28 is therefore electrically conductive. For example, the bond layer 28 is a SiO/Cu hybrid bond layer.

The invention is not limited to the description of the embodiments. Rather, the invention comprises each new feature as well as each combination of features, particularly each combination of features of the claims, even if the feature or the combination of features itself is not explicitly given in the claims or embodiments.

1.-15. (canceled)

16. A method for manufacturing a plurality of semiconductor chips, the method comprising:
providing an epitaxial semiconductor layer sequence having a plurality of epitaxial semiconductor layer stacks, the epitaxial semiconductor layer stacks having active regions configured for generating electromagnetic radiation;
applying a plurality of logical chips on or over the epitaxial semiconductor layer sequence, the logical chips comprising at least one integrated circuit configured for controlling the active regions, wherein the logical chips are at least partially provided separately from each other, and wherein the logical chips are CMOS chips, the CMOS chips comprising at least one p-channel MOSFET and at least one n-channel MOSFET being part of the at least one integrated circuit; and
embedding the plurality of logical chips in a mold compound.

17. The method according to claim 16,
wherein the epitaxial semiconductor layer sequence is arranged on a carrier, and
wherein the carrier is removed after the mold compound is applied.

18. The method according to claim 16, further comprising:
removing the mold compound against a vertical direction such that backside surfaces of the logical chips are exposed; and
applying a metal layer on the backside surface of the logical chips.

19. The method according to claim 16, further comprising applying protection structures on or over the epitaxial semiconductor layer sequence before applying the mold compound.

20. The method according to claim 19, wherein the protection structures are walls applied by plating.

21. The method according to claim 19, wherein the protection structures exceed the logical chips in a vertical direction.

22. The method according to claim 16, further comprising forming contrast enhancement structures within the epitaxial semiconductor layer sequence separating the epitaxial semiconductor layer stacks in at least two pixel regions.

23. The method according to claim 16, further comprising applying a plurality of communication chips on or over the logical chips.

24. The method according to claim 16, further comprising applying a wavelength converter on or over a main surface of the epitaxial semiconductor layer sequence.

25. A semiconductor chip comprising:
an epitaxial semiconductor layer stack having an active region configured for generating electromagnetic radiation; and
a logical chip comprising at least one integrated circuit configured to control the active region,
wherein the logical chip is laterally at least partially embedded in a mold compound,
wherein the epitaxial semiconductor layer stack has at least two pixel regions comprising parts of the active region,
wherein bumps are electrically conductively connecting the pixel regions with the logical chip,
wherein the logical chip controls the parts of the active regions of the pixel regions independently from each other, and
wherein the epitaxial semiconductor layer stack and the logical chip are arranged offset to each other such that an electrical contact pad of the logical chip is freely accessible.

26. The semiconductor chip according to claim 25, wherein at least outer bumps adjacent to a side face of the semiconductor chip are covered with the mold compound.

27. The semiconductor chip according to claim 25, further comprising a communication chip arranged on or over a backside surface of the logical chip.
